(19) United States
(12) Patent Application Publication
(10) Pub. No.: US 2026/0360665 A1
(43) Pub. Date: Nov. 12, 2026

(54) CHARGED PARTICLE BEAM WRITING METHOD, CHARGED PARTICLE BEAM WRITING APPARATUS, AND NON-TRANSITORY COMPUTER-READABLE STORAGE MEDIUM STORING PROGRAM

(71) Applicant: NuFlare Technology, Inc., Yokohama-shi (JP)

(72) Inventors: Hiroshi MATSUMOTO, Yokohama-shi (JP); Haruyuki NOMURA, Yokohama-shi (JP)

(73) Assignee: NuFlare Technology, Inc., Yokohama-shi (JP)

(21) Appl. No.: 19/649,316

(22) Filed: Apr. 16, 2026

(30) Foreign Application Priority Data
May 7, 2025 (JP) 2025-077472

(51) Int. Cl. H01J 37/302; H01J 37/317

(52) U.S. Cl. CPC H01J 37/3023; H01J 37/3174; H01J 2237/30455

(57) ABSTRACT

According to one aspect of the present invention, a charged particle beam writing method, includes: calculating a pattern area density of a figure arranged in each of a plurality of small regions, each small region being an irradiation unit region of a charged particle beam obtained by dividing a writing region of a target object; calculating an exposure intensity for each of the small regions; calculating, for each pattern area density, a function to provide a desired exposure intensity gradient; calculating, for each of the small regions, a corrected exposure intensity of the small region using a function corresponding to the pattern area density of the small region; and writing a pattern on the target object using a charged particle beam based on the corrected exposure intensity.

### CROSS-REFERENCE TO RELATED APPLICATION

This application is based upon and claims the benefit of priority from prior Japanese Patent Application No. 2025-077472 filed on May 7, 2025 in Japan, the entire contents of which are incorporated herein by reference.

### BACKGROUND OF THE INVENTION

### Field of the Invention

One aspect of the present invention relates to a charged particle beam writing (or “drawing”) method, a charged particle beam writing apparatus, and a non-transitory computer-readable storage medium storing a program, and for example, relates to a method for reproducing older-generation pattern writing using a multi-beam writing apparatus for advanced processes.

### Related Art

Lithography technology, which is responsible for the progress of miniaturization of semiconductor devices, is an extremely important process that is the only pattern generation process among the semiconductor manufacturing processes. In recent years, as LSIs have become more highly integrated, the circuit pattern linewidth required for semiconductor devices has become smaller year by year. Here, electron beam writing technology is basically excellent in terms of resolution, and writing is performed on wafers and the like using an electron beam.

For example, there is a writing apparatus using multiple beams. Compared to the case of writing using a single electron beam, using multiple beams allows irradiation using a large amount of beams at a time, resulting in a significant improvement in throughput. In such a multi-beam type writing apparatus, for example, an electron beam emitted from an electron emission source passes through a mask having a plurality of holes to form multiple beams, and each of the multiple beams is subjected to blanking control so that each beam that is not blocked is demagnified by an optical system, deflected by a deflector, and emitted to a desired position on a target object.

Here, in multi-beam writing, for example, there is a case where it is required to write a pattern with a precision, which is equivalent to that obtained by an older-generation low-precision writing apparatus, using a high-precision writing apparatus used for advanced processes and the like. For example, there is a case where it is desired to create the same product as a product created in the past or a case where the performance required for the semiconductor device of the final product may be that of the older generation. For example, since not all of the manufactured masks are state-of-the-art products, if a high-precision writing apparatus can write a pattern on a mask substrate with a precision equivalent to that obtained by the older-generation writing apparatus using a high-precision writing apparatus, the idle time of the writing apparatus can be used effectively.

However, in a high-precision writing apparatus for advanced processes, the beam resolution is high, and accordingly, the pattern resolution and the pattern fidelity are different from those of the older-generation writing apparatus. For this reason, it is necessary to match the resolution performance of the writing apparatus for advanced processes to that of the older-generation writing apparatus. One of the methods is to match the exposure dose distribution obtained by a writing apparatus for advanced processes to the exposure dose distribution obtained by an older-generation mask process using an older-generation writing apparatus. In order to achieve this, a process is required to blur the exposure dose distribution obtained by the writing apparatus for advanced processes so as to match the exposure dose distribution obtained by the older-generation mask process using the older-generation writing apparatus.

Here, a technique has been disclosed that does not blur the exposure dose distribution so as to match the specifications of the older generation but corrects positional deviations by weighting the exposure intensity of a plurality of beams to be emitted to pixels to be subjected to multi-writing (see Published Unexamined Japanese Patent Application No. 2016-103557, for example).

### BRIEF SUMMARY OF THE INVENTION

According to one aspect of the present invention, a charged particle beam writing method, includes:
calculating a pattern area density of a figure arranged in each of a plurality of small regions, each small region being an irradiation unit region of a charged particle beam obtained by dividing a writing region of a target object;
calculating an exposure intensity for each of the small regions;
calculating, for each pattern area density, a function to provide a desired exposure intensity gradient;
calculating, for each of the small regions, a corrected exposure intensity of the small region using a function corresponding to the pattern area density of the small region; and
writing a pattern on the target object using a charged particle beam based on the corrected exposure intensity.

According to another aspect of the present invention, a charged particle beam writing apparatus, includes:
a pattern area density calculation circuit configured to calculate a pattern area density of a figure arranged in each of a plurality of small regions, each small region being an irradiation unit region of a charged particle beam obtained by dividing a writing region of a target object;
an exposure intensity calculation circuit configured to calculate an exposure intensity for each of the small regions;
a function calculation circuit configured to calculate, for each pattern area density, a function to provide a desired exposure intensity gradient;
a corrected exposure intensity calculation circuit configured to calculate, for each of the small regions, a corrected exposure intensity of the small region using a function corresponding to the pattern area density of the small region; and
a writing mechanism configured to write a pattern on the target object using a charged particle beam based on the corrected exposure intensity.

According to yet another aspect of the present invention, a non-transitory computer-readable storage medium storing a program for causing a computer to execute processing includes:
calculating a pattern area density of a figure arranged in each of a plurality of small regions, each small region being an irradiation unit region of a charged particle beam obtained by dividing a writing region of a target object;
storing the pattern area density for each of the small regions in a storage device;
reading the pattern area density for each of the small regions from the storage device and calculating an exposure intensity for each of the small regions;
calculating, for each pattern area density, a function to provide a desired exposure intensity gradient; and
calculating, for each of the small regions, a corrected exposure intensity of the small region using a function corresponding to the pattern area density of the small region and outputting the calculated corrected exposure intensity.

### BRIEF DESCRIPTION OF THE DRAWINGS

FIG. 1 is a conceptual diagram showing an example of the configuration of a writing apparatus according to Embodiment 1;

FIG. 2 is a conceptual diagram showing an example of the configuration of a shaping aperture array substrate in Embodiment 1;

FIG. 3 is a cross-sectional view showing an example of the configuration of a blanking aperture array mechanism in Embodiment 1;

FIG. 4 is a conceptual diagram for explaining an example of a writing operation in Embodiment 1;

FIG. 5 is a diagram showing an example of an irradiation region irradiated with multiple beams and a writing target pixel in Embodiment 1;

FIG. 6 is a diagram for explaining total blur in Embodiment 1;

FIG. 7 is a diagram for explaining a dose distribution when an exposure intensity is convolved with a kernel in Comparative Example 1 of Embodiment 1;

FIG. 8 is a diagram showing an example of the exposure intensity and the accumulated dose for pixels of an on-grid pattern in which the area density of pattern-edge pixels, that is, the pattern coverage rate of pixels, is 100% in Comparative Example 2 of Embodiment 1;

FIG. 9 is a diagram showing an example of the exposure intensity and the accumulated dose for pixels of an off-grid pattern in which the area density of pattern-edge pixels, that is, the pattern coverage rate of pixels, is 25% in Comparative Example 2 of Embodiment 1;

FIG. 10 is a diagram showing an example of the exposure intensity and the accumulated dose when an additional blur is added to pixels of an on-grid pattern in Comparative Example 2 of Embodiment 1;

FIG. 11 is a diagram showing an example of the exposure intensity and the accumulated dose when an additional blur is added to pixels of an off-grid pattern with an area density of 25% in Comparative Example 2 of Embodiment 1;

FIG. 12 is a diagram showing an example of an intensity distribution when the standard deviation and the shift amount are varied in Embodiment 1;

FIG. 13 is a diagram for explaining exposure intensity correction calculation using a fixed point spread function in Comparative Example 3 of Embodiment 1;

FIG. 14 is a diagram for explaining exposure intensity correction calculation using a point spread function dependent on edge position information in Embodiment 1;

FIG. 15 is a diagram showing an example of the exposure intensity and the accumulated dose when an additional blur is added to pixels of an off-grid pattern in which the area density of pattern-edge pixels is 25% in Comparative Example 3 of Embodiment 1;

FIG. 16 is a diagram showing another example of the exposure intensity and the accumulated dose when an additional blur is added to pixels of an off-grid pattern in which the area density of pattern-edge pixels is 25% in Embodiment 1;

FIG. 17 is a diagram showing another example of the exposure intensity and the accumulated dose when an additional blur is added to pixels of an off-grid pattern with an area density of 25% in Embodiment 1;

FIG. 18 is a diagram showing an example of the exposure intensity and the accumulated dose when an additional blur is added to pixels of an off-grid pattern with an area density of 50% in Embodiment 1;

FIG. 19 is a diagram showing an example of the exposure intensity and the accumulated dose when an additional blur is added to pixels of an off-grid pattern with an area density of 75% in Embodiment 1;

FIG. 20 is a flowchart showing an example of main steps of a writing method according to Embodiment 1;

FIG. 21 is a diagram showing an example of the relationship between a dimensional variation and the exposure intensity in Embodiment 1;

FIG. 22 is a diagram showing an example of the relationship among the shift amount, the dimensional variation, and the exposure intensity in an off-grid pattern in Embodiment 1;

FIG. 23 is a diagram showing an example of the relationship between the shift amount and the pattern area density in Embodiment 1; and

FIG. 24 is a diagram for explaining an example of a multi-beam writing operation in Embodiment 1.

### DETAILED DESCRIPTION OF THE INVENTION

One aspect of the invention provides a writing method and a writing apparatus that can write a pattern with an exposure dose distribution obtained by a low-precision writing apparatus, without replacing hardware, using a high-precision writing apparatus.

In the following embodiments, a configuration using an electron beam as an example of a charged particle beam will be described. However, the charged particle beam is not limited to an electron beam, and may be a beam using a charged particle such as an ion beam. In addition, as an example of the writing apparatus, a writing apparatus using multiple beams is described. However, a writing apparatus may be used that performs raster scanning using a single beam, without being limited to multiple beams.

### Embodiment 1

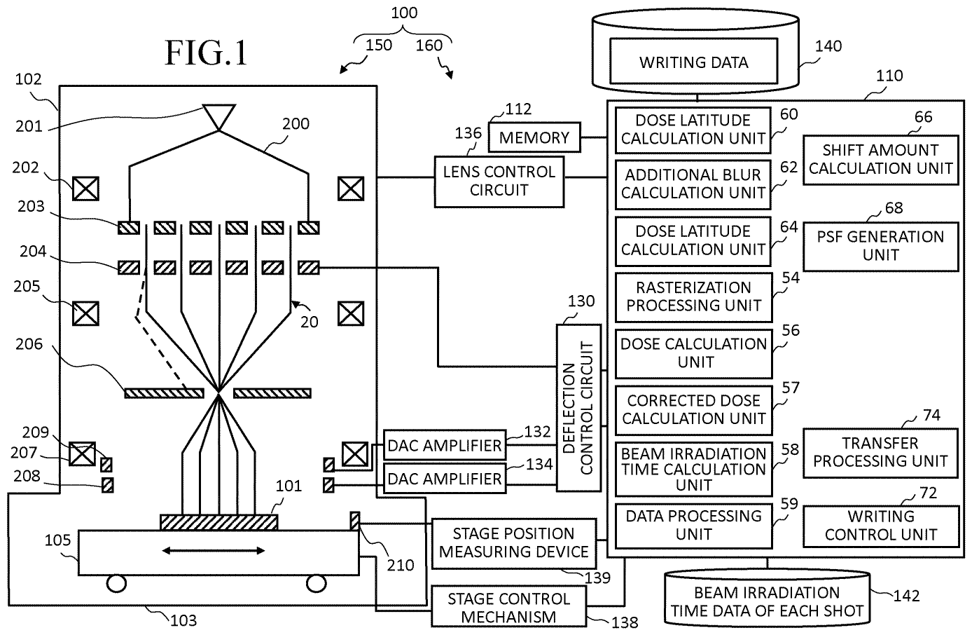

FIG. 1 is a conceptual diagram showing an example of the configuration of a writing apparatus according to Embodiment 1. In FIG. 1, a writing apparatus 100 includes a writing mechanism 150 and a control system circuit 160. The writing apparatus 100 is an example of a multi-charged particle beam writing apparatus and an example of a multi-charged particle beam exposure apparatus. The writing mechanism 150 includes an electron optical column 102 (electron beam column) and a writing chamber 103. An electron emission source 201, an illumination lens 202, a shaping aperture array substrate 203, a blanking aperture array mechanism 204, a demagnifying lens 205, a limiting aperture substrate 206, an objective lens 207, a main deflector 208, and a sub-deflector 209 are arranged in the electron optical column 102.

An XY stage 105 is arranged in the writing chamber 103. On the XY stage 105, a target object 101 such as a mask, which becomes a writing target substrate during writing (during exposure), is arranged. The target object 101 includes an exposure mask used in manufacturing a semiconductor device, a semiconductor substrate (silicon wafer) on which a semiconductor device is manufactured, and the like. In addition, the target object 101 includes a mask blank which is coated with resist and on which nothing has been written yet. A mirror 210 for measuring the position of the XY stage 105 is further arranged on the XY stage 105.

The control system circuit 160 includes a control calculator 110, a memory 112, a deflection control circuit 130, digital-to-analog conversion (DAC) amplifier units 132 and 134, a lens control circuit 136, a stage control mechanism 138, a stage position measuring device 139, and storage devices 140 and 142 such as magnetic disk drives. The control calculator 110, the memory 112, the deflection control circuit 130, the lens control circuit 136, the stage control mechanism 138, the stage position measuring device 139, and the storage devices 140 and 142 are connected to each other through a bus (not shown). The DAC amplifier units 132 and 134 and the blanking aperture array mechanism 204 are connected to the deflection control circuit 130. The sub-deflector 209 is configured by electrodes having four or more poles, and each electrode is controlled by the deflection control circuit 130 through the DAC amplifier 132. The main deflector 208 is configured by electrodes having four or more poles, and each electrode is controlled by the deflection control circuit 130 through the DAC amplifier 134. A group of lenses such as the illumination lens 202, the demagnifying lens 205, and the objective lens 207 are controlled by the lens control circuit 136.

The position of the XY stage 105 is controlled by driving motors for each axis (not shown) controlled by the stage control mechanism 138. The stage position measuring device 139 measures the position of the XY stage 105 using the principle of laser interferometry by receiving the reflected light from the mirror 210.

A rasterization processing unit 54, an exposure intensity calculation unit 56, a corrected exposure intensity calculation unit 57, a beam irradiation time calculation unit 58, a data processing unit 59, a margin calculation unit 60, an additional blur calculation unit 62, a margin calculation unit 64, a shift amount calculation unit 66, a PSF (point spread function) generation unit 68, a writing control unit 72, and a transfer processing unit 74 are arranged in the control calculator 110.

Each of the “~ units”, such as the rasterization processing unit 54, the exposure intensity calculation unit 56, the corrected exposure intensity calculation unit 57, the beam irradiation time calculation unit 58, the data processing unit 59, the margin calculation unit 60, the additional blur calculation unit 62, the margin calculation unit 64, the shift amount calculation unit 66, the PSF generation unit 68, the writing control unit 72, and the transfer processing unit 74, has a processing circuit. Examples of such a processing circuit include an electric circuit, a computer, a processor, a circuit board, a quantum circuit, and a semiconductor device. For the respective “~ units”, a common processing circuit (the same processing circuit) may be used or different processing circuits (separate processing circuits) may be used. Information input to and output from the rasterization processing unit 54, the exposure intensity calculation unit 56, the corrected exposure intensity calculation unit 57, the beam irradiation time calculation unit 58, the data processing unit 59, the margin calculation unit 60, the additional blur calculation unit 62, the shift amount calculation unit 66, the PSF generation unit 68, the writing control unit 72, and the transfer processing unit 74 and information being calculated are stored in the memory 112 as needed.

The writing operation of the writing apparatus 100 is controlled by the writing control unit 72. In addition, processing for the transfer of beam irradiation time data of each shot to the deflection control circuit 130 is controlled by the transfer processing unit 74.

In addition, writing data (chip data) is input from outside the writing apparatus 100 and is stored in the storage device 140. The chip data defines information of a plurality of figures forming a chip pattern. Specifically, for each figure, for example, the coordinates of each vertex are defined in the order in which they form the figure. Alternatively, for each figure, for example, a figure code, coordinates, size, and the like are defined.

Here, FIG. 1 describes components necessary for explaining Embodiment 1. The writing apparatus 100 may also include other components that are normally required.

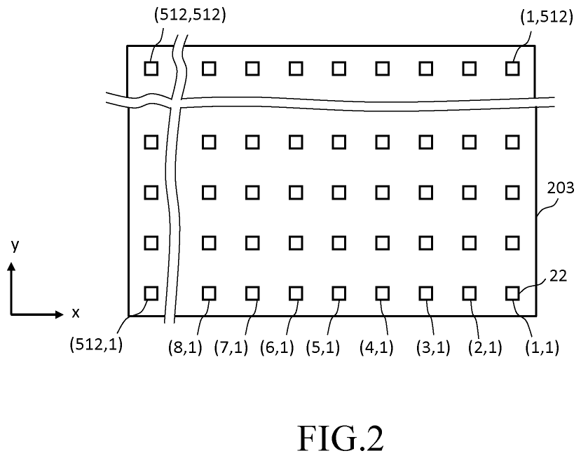

FIG. 2 is a conceptual diagram showing an example of the configuration of a shaping aperture array substrate in Embodiment 1. In FIG. 2, in the shaping aperture array substrate 203, holes (openings) 22 are formed in a matrix of p columns wide (x direction) and q rows long (y direction) (p, q≥2) at predetermined arrangement pitches. In the example of FIG. 2, for example, 512×512 holes 22 are formed in length and width directions (x and y directions). The number of holes 22 is not limited thereto. For example, 32×32 holes 22 may be formed. The holes 22 are formed in rectangles having the same dimension and shape. Alternatively, the holes 22 may be circles having the same diameter. Some of electron beams 200 pass through the plurality of holes 22 to form multiple beams 20. In other words, the shaping aperture array substrate 203 forms and emits the multiple beams 20. The shaping aperture array substrate 203 is an example of an emission source of the multiple beams 20 or a multi-beam forming mechanism.

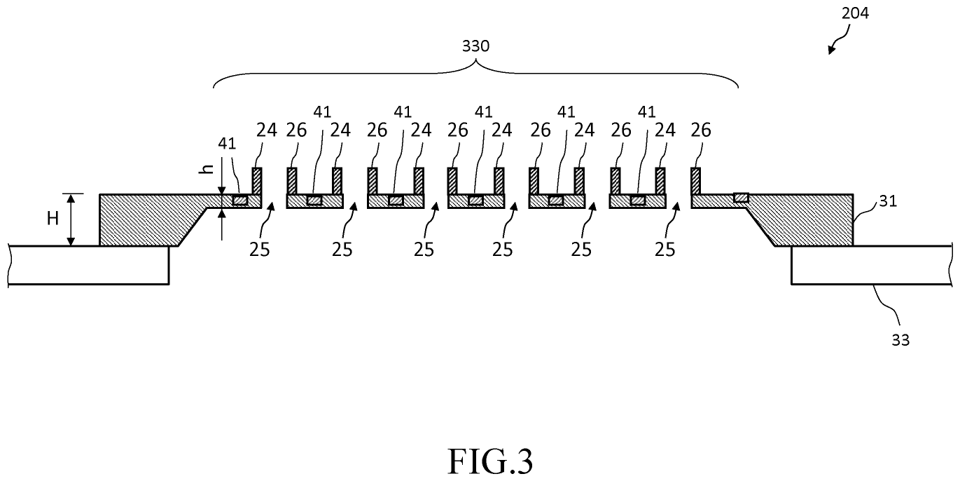

FIG. 3 is a cross-sectional view showing an example of the configuration of a blanking aperture array mechanism in Embodiment 1. In the blanking aperture array mechanism 204, as shown in FIG. 3, a blanking aperture array substrate 31 using a semiconductor substrate formed of silicon or the like is arranged on a support base 33. In a membrane region 330 at the center of the blanking aperture array substrate 31, a passage hole 25 (opening) through which each of the multiple beams 20 passes is opened at a position corresponding to each hole 22 of the shaping aperture array substrate 203 shown in FIG. 2. Then, a set of a control electrode 24 and a counter electrode 26 (blanker: blanking deflector) are arranged at positions facing each other with a corresponding passage hole 25 among the plurality of passage holes 25 interposed therebetween. In addition, a control circuit 41 (logic circuit) to apply a deflection voltage to the control electrode 24 for each passage hole 25 is arranged inside the blanking aperture array substrate 31 near each passage hole 25. The counter electrode 26 for each beam is grounded.

In the control circuit 41, an amplifier (an example of a switching circuit), which is not shown, is arranged. As an example of the amplifier, a complementary MOS (CMOS) inverter circuit serving as a switching circuit is arranged. Either a low (L) potential (for example, ground potential) that is lower than the threshold voltage or a high (H) potential (for example, 1.5 V) that is equal to or higher than the threshold voltage is applied to the input (IN) of the CMOS inverter circuit as a control signal. In Embodiment 1, in a state in which the L potential is applied to the input (IN) of the CMOS inverter circuit, the output (OUT) of the CMOS inverter circuit applied to the control circuit 41 has a positive potential (Vdd), and the corresponding beam is deflected by the electric field due to the potential difference from the ground potential of the counter electrode 26 and shielded by the limiting aperture substrate 206. In this manner, the beam is controlled to be turned off. On the other hand, in a state in which the H potential is applied to the input (IN) of the CMOS inverter circuit (active state), the output (OUT) of the CMOS inverter circuit has a ground potential, and there is no potential difference from the ground potential of the counter electrode 26. Therefore, since the corresponding beam is not deflected, the beam passes through the limiting aperture substrate 206. In this manner, the beam is controlled to be turned on. Blanking control is made by such deflection.

Next, a specific example of the operation of the writing mechanism 150 will be described. An electron beam 200 emitted from the electron emission source 201 (emission source) illuminates the entire shaping aperture array substrate 203 almost vertically through the illumination lens 202. A plurality of rectangular holes 22 (openings) are formed in the shaping aperture array substrate 203, and the electron beam 200 illuminates a region including all of the plurality of holes 22. Some of the electron beams 200 emitted to the positions of the plurality of holes 22 pass through the plurality of holes 22 in the shaping aperture array substrate 203 to form, for example, rectangular multiple beams (a plurality of electron beams) 20. Such multiple beams 20 pass through corresponding blankers of the blanking aperture array mechanism 204. Each of the blankers performs blanking control on a beam passing therethrough individually so that the beam is in an ON state for a set writing time (beam irradiation time).

The multiple beams 20 that have passed through the blanking aperture array mechanism 204 are reduced by the demagnifying lens 205 and travel toward a central hole formed in the limiting aperture substrate 206. Here, the electron beam deflected by the blanker of the blanking aperture array mechanism 204 is shifted away from the central hole of the limiting aperture substrate 206 and is blocked by the limiting aperture substrate 206. On the other hand, the electron beam that is not deflected by the blanker of the blanking aperture array mechanism 204 passes through the central hole of the limiting aperture substrate 206 as shown in FIG. 1. Thus, the limiting aperture substrate 206 blocks each beam that is deflected by the blanker of the blanking aperture array mechanism 204 so as to be in a beam OFF state. Then, by the beam that has passed through the limiting aperture substrate 206 and is formed from the beam ON state to the beam OFF state, each beam of one shot is formed. The multiple beams 20 that have passed through the limiting aperture substrate 206 are focused by the objective lens 207 to become a pattern image having a desired reduction ratio, and all of the multiple beams 20 that have passed through the limiting aperture substrate 206 are collectively deflected in the same direction by the main deflector 208 and the sub-deflector 209 and emitted to each irradiation position on the target object 101 of each beam. In addition, for example, when the XY stage 105 is continuously moving, tracking control is performed by the main deflector 208 so that the irradiation position of the beam follows the movement of the XY stage 105. The multiple beams 20 emitted at one time are ideally arranged at a pitch obtained by multiplying the arrangement pitch of the plurality of holes 22 of the shaping aperture array substrate 203 by the desired reduction ratio described above.

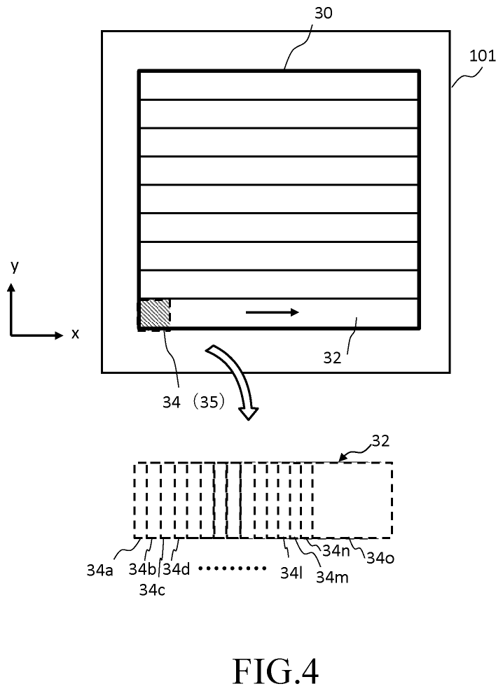

FIG. 4 is a conceptual diagram for explaining an example of the writing operation in Embodiment 1. As shown in FIG. 4, a writing region 30 (thick line) of the target object 101 is virtually divided into a plurality of rectangular stripe regions 32 with a predetermined width in the y direction, for example. The example in FIG. 4 shows a case where the writing region 30 of the target object 101 is divided into a plurality of stripe regions 32, for example, in the y direction, with the substantially the same width as the size of the designed irradiation region 34 (writing field) that can be irradiated with one-time multiple beams 20.

First, the XY stage 105 is moved to make an adjustment so that the irradiation region 34 irradiated with the multiple beams 20 is located at the left end of the first stripe region 32 or further to the left, and writing in the first stripe region 32 is performed. When writing the first stripe region 32, the XY stage 105 is moved, for example, in the −x direction, so that the writing proceeds relatively in the x direction. The XY stage 105 is continuously moved, for example, at a constant speed. After the writing in the first stripe region 32 ends, the stage position is moved in the −y direction by the width of the stripe region 32.

Then, an adjustment is made so that the irradiation region 34 irradiated with the multiple beams 20 is located at the left end of the second stripe region 32 or further to the left, and the XY stage 105 is moved, for example, in the −x direction so that the writing proceeds relatively in the x direction. In this manner, the writing in the second stripe region 32 is performed.

In addition, although the case where the writing in each stripe region 32 proceeds in the same direction is shown in the example described above, the invention is not limited thereto. For example, for the stripe region 32 to be written next to the stripe region 32 where writing has been performed in the x direction, the writing may be performed in the −x direction by moving the XY stage 105, for example, in the x direction. By performing writing while alternately changing the direction in this manner, the stage movement time can be shortened, and the writing time can be shortened. In one shot, by the multiple beams formed by passing through each hole 22 of the shaping aperture array substrate 203, a plurality of shot patterns, up to the same number as each hole 22, are formed at a time.

In addition, although the example in FIG. 4 shows a case where the stage movement for writing in each stripe region is performed once at a time, the invention is not limited thereto. It is also preferable to perform multi-writing (multi-pass writing) by moving the stage over the same position a plurality of times. In this case, for example, when performing multi-pass writing N times, it is preferable to perform multi-writing while shifting in the y direction by a shift amount of 1/N of the width of the stripe region. Alternatively, it is also preferable to perform multi-writing (in-pass multi-writing) in which the same position is written a plurality of times with different beams during one stage movement.

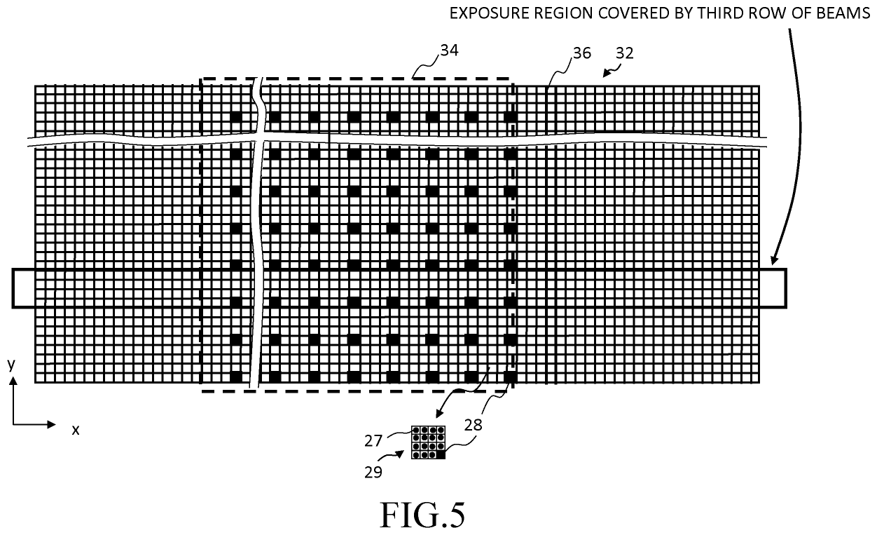

FIG. 5 is a diagram showing an example of an irradiation region irradiated with multiple beams and a writing target pixel in Embodiment 1. In FIG. 5, the stripe region 32 is divided into a plurality of mesh regions with the beam size of the multiple beams 20, for example. Each of the mesh regions becomes a pixel 36 (beam irradiation unit region, irradiation position) to be written. The size of the writing target pixel 36 is not limited to the beam size, and may be any size regardless of the beam size. For example, the size of the writing target pixel 36 may be 1/n (n is an integer of 1 or more) of the beam size. The example in FIG. 5 shows a case where the writing region of the target object 101 is divided into a plurality of stripe regions 32, for example, in the y direction, with the substantially the same width as the size of the irradiation region 34 (writing field) that can be irradiated with one-time multiple beams 20. The size of the designed rectangular irradiation region 34 in the x direction can be defined as the number of beams in the x direction×the pitch between beams in the x direction. The size of the irradiation region 34 in the y direction can be defined as the number of beams in the y direction×the pitch between beams in the y direction. In the example of FIG. 5, for example, 512×512 multiple beams are abbreviated to 8×8 multiple beams. Then, in the irradiation region 34, a plurality of pixels 28 (beam writing positions) that can be irradiated with one shot of the multiple beams 20 are shown. The pitch between the pixels 28 adjacent to each other is the pitch between the multiple beams. A rectangular region surrounded with the size of the beam pitch in the x and y directions is one sub-irradiation region 29 (pitch cell region). The example in FIG. 5 shows a case where each sub-irradiation region 29 is formed by, for example, 4×4 pixels.

In addition, each pixel 36 is formed with each writing grid 27 as its center. Ideally, each writing grid 27 matches a different one of a plurality of ideal grids arranged at equal pitch on a plurality of lattice-like straight lines. For example, each writing grid 27 matches a different one of a plurality of ideal grids arranged at the intersections of a plurality of lattice-like straight lines arranged at equal pitches.

Here, as described above, in multi-beam writing, for example, there is a case where it is required to write a pattern with a precision, which is equivalent to that obtained by a low-precision writing apparatus of the older generation, using a high-precision writing apparatus of the current generation that is used for advanced processes and the like.

However, in a high-precision writing apparatus for advanced processes, the beam resolution is high, and accordingly, the pattern resolution and the pattern fidelity are different from those of the older-generation writing apparatus. For this reason, it is necessary to match the resolution performance of the writing apparatus for advanced processes to that of the older-generation writing apparatus. One of the methods is to match the exposure dose distribution obtained by a writing apparatus for advanced processes to the exposure dose distribution obtained by an older-generation mask process using an older-generation writing apparatus by intentionally lowering the resolution of the exposure dose distribution obtained by the writing apparatus for advanced processes. In order to achieve this, a process is required to blur the exposure dose distribution obtained by the writing apparatus for advanced processes so as to match the exposure dose distribution obtained by the older-generation mask process using the older-generation writing apparatus.

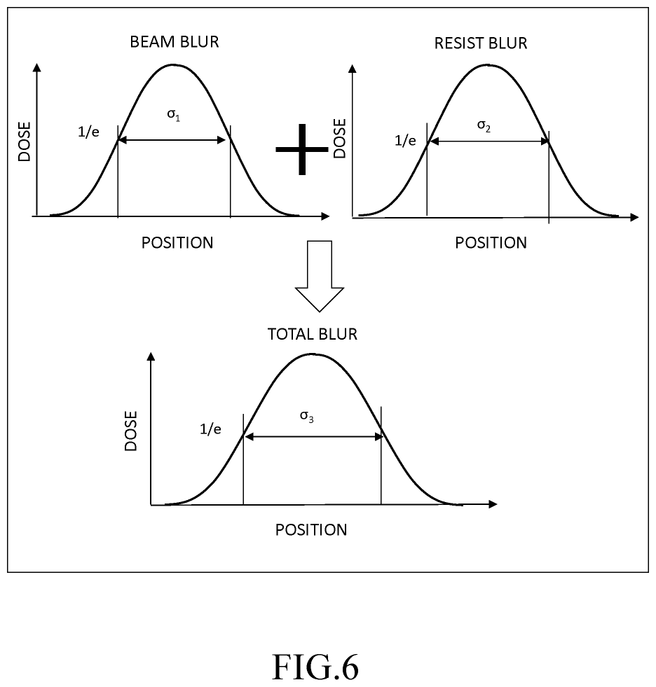

FIG. 6 is a diagram for explaining total blur in Embodiment 1. In addition to blur (beam blur) indicating the spread of the beam caused by the optical system, blur at the development stage (resist blur: process blur), which indicates the spread of the electron due to acid diffusion in the resist irradiated with the beam, occurs in the electron beam. Using the standard deviation σ₁ of the distribution function of the beam blur and the standard deviation σ₂ of the distribution function of the resist blur, the distribution function gₜ(x) of the total blur can be defined by the following Equation (1-1) using, for example, a Gaussian distribution function. The standard deviation σ₃ of the distribution function of the total blur can be defined by Equation (1-2). In Equation (1-1), A is a coefficient for normalization.

$${g}_{t} ( x ) = A exp ( - \frac{{x}^{2}}{{σ}_{3}^{2}} ) \qquad ( 1 - 1 )$$

$${σ}_{3} = \sqrt{{σ}_{1}^{2} + {σ}_{2}^{2}} \qquad ( 1 - 2 )$$

Then, the exposure dose distribution d″(x) after development at the irradiation position of the target object 101 can be defined by the following Equation (2) using an exposure intensity d(x).

[Equation 2]

d″(x)=∫d(x−x′)gₜ(x′)dx′ (2)

In Embodiment 1, in order to match the resolution performance of the writing apparatus for advanced processes to the resolution performance of the older-generation writing apparatus, an additional blur is further added. The additional blur can be added by convolving the exposure intensity d(x) with a kernel g(x) that smooths the exposure intensity gradient. In Embodiment 1, an additional blur is added by using a method different from convolution. However, as Comparative Example 1 of Embodiment 1, a method of adding an additional blur by convolution using Equation (2) will be shown below.

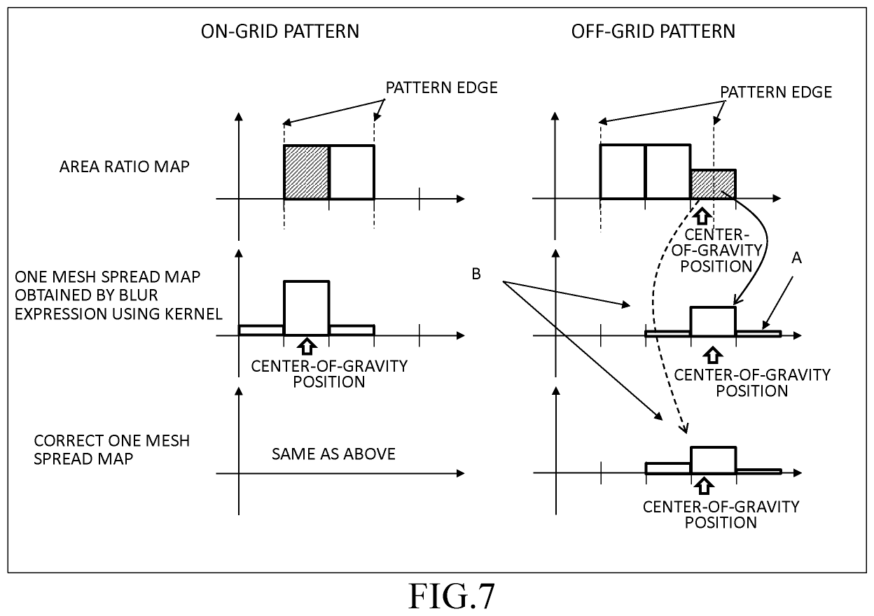

FIG. 7 is a diagram for explaining a dose distribution when an exposure intensity is convolved with a kernel in Comparative Example 1 of Embodiment 1. In the example of FIG. 7, an example of the spread of the exposure intensity of one pixel when the exposure intensity of each pixel is convolved with a kernel is shown. In the example of FIG. 7, a kernel is used that evenly distributes a part of the exposure intensity of the target pixel 36 to the surrounding pixels.

In addition, in the example of FIG. 7, an example of the spread of the exposure intensity of one pixel of an on-grid pattern, in which the edge of the figure matches the edge of the pixel 36 (small region), and an example of the spread of the exposure intensity of one pixel of an off-grid pattern, in which the edge of the figure does not match the edge of the pixel 36 (small region), are shown. In the on-grid pattern, the spread of the exposure intensity from the target pixel with the center of the pixel as its center-of-gravity position is obtained by convolution using the kernel. In contrast, in the off-grid pattern, as shown in part A, the exposure intensity distribution that has been spread by rasterization processing is further spread by convolution using the kernel. In addition, in the off-grid pattern, as shown in part B, the convolution operation causes the center-of-gravity position of the exposure intensity distribution to deviate from the center-of-gravity position of the figure arranged in the pixel. Therefore, there is a problem that a correct exposure intensity distribution cannot be obtained.

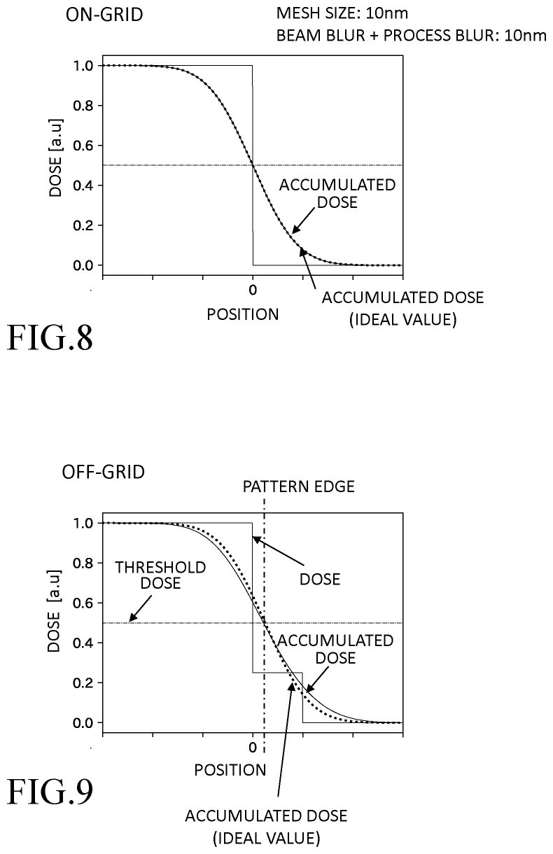

FIG. 8 is a diagram showing an example of the exposure intensity and the accumulated dose for pixels of an on-grid pattern in which the area density of pattern-edge pixels, that is, the pattern coverage rate of pixels, is 100% in Comparative Example 2 of Embodiment 1.

FIG. 9 is a diagram showing an example of the exposure intensity and the accumulated dose for pixels of an off-grid pattern in which the area density of pattern-edge pixels, that is, the pattern coverage rate of pixels, is 25% in Comparative Example 2 of Embodiment 1.

In the examples of FIGS. 8 and 9, a case is shown in which the pixel size is 10 nm and the blur size is 10 nm as the sum of beam blur and process blur. Here, an exposure intensity distribution at one-side edge of a pattern having a dimension larger than the beam blur is shown. In a pixel of an on-grid pattern, as shown in FIG. 8, the accumulated dose of the resist after writing matches an ideal value, that is, an accumulated dose when the pixel size and the beam size are infinitesimal. In contrast, gray writing of a pixel (a gray pixel in which the pattern area density is greater than 0% and less than 100%) of the off-grid pattern has an effect of smoothing the accumulated dose distribution. That is, a distribution that is gentler than the ideal accumulated dose distribution is obtained. Therefore, in a pixel of an off-grid pattern, when an exposure intensity proportional to the pattern area density is used, the accumulated dose distribution deviates slightly from the ideal accumulated dose, as shown in FIG. 9. In addition, this causes a deviation in the intersection position between the threshold dose and the accumulated dose, which results in a deviation in the position of the edge of the resist pattern formed by development. This problem is known as gray beam writing error, and is noticeable when the beam size and the pixel size are not sufficiently small compared with the blur.

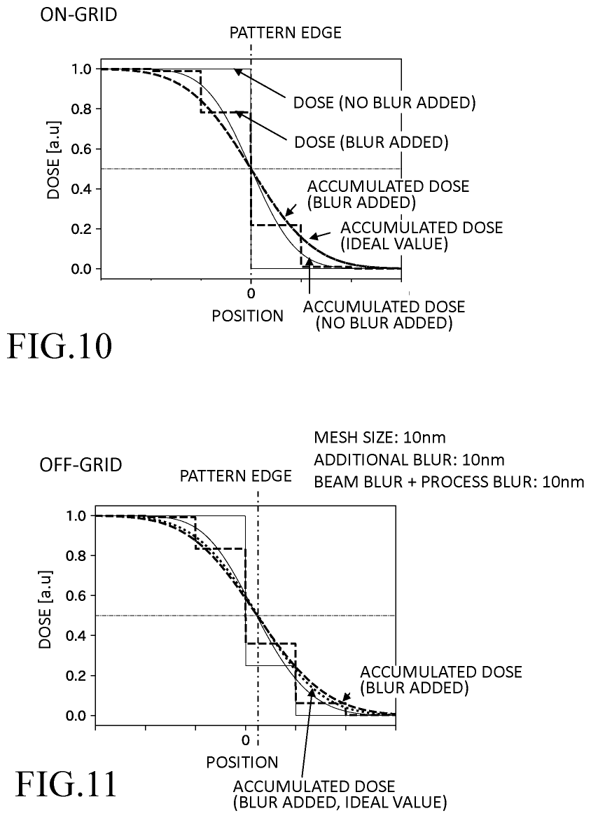

FIG. 10 is a diagram showing an example of the exposure intensity and the accumulated dose when an additional blur is added to pixels of an on-grid pattern in Comparative Example 2 of Embodiment 1.

FIG. 11 is a diagram showing an example of the exposure intensity and the accumulated dose when an additional blur is added to pixels of an off-grid pattern with an area density of 25% in Comparative Example 2 of Embodiment 1.

In the examples of FIGS. 10 and 11, a case is shown in which an additional blur of 10 nm is added to the examples of FIGS. 8 and 9 by Equation (2). By adding an additional blur, a part of the exposure intensity at a pattern-edge pixel of the on-grid pattern is distributed to adjacent pixels. Even in such a case, in a pixel of an on-grid pattern with the additional blur added, as shown in FIG. 10, the accumulated dose of the resist after writing matches an ideal value. In contrast, for pixels of an off-grid pattern, by adding additional blur, the accumulated dose in the resist after writing approaches the ideal value, but does not match, as shown in FIG. 11. In contrast, in a pixel of an off-grid pattern, it can be seen that, by adding the additional blur, the accumulated dose of the resist after writing approaches the ideal value but does not match the ideal value, as shown in FIG. 11.

As described above, in Comparative Example 2, by convolving the exposure intensity for each pixel with the same kernel in order to add the additional blur to the exposure intensity distribution, the same amount of additional blur is added to both the on-grid pattern and the off-grid pattern. The area ratio map, which is the input of the convolution operation, is a mathematical representation in which the dose is uniformly spread within a pixel. Then, when convolution processing is performed, this dose spread is preserved even after the convolution operation. Therefore, in a pixel of an off-grid pattern, the blur of the exposure intensity distribution is larger than that in a pixel of an on-grid pattern, and this difference ultimately remains in the exposure intensity distribution.

Therefore, in Embodiment 1, a point spread function (PSF) dependent on edge position information is used as a kernel, and the exposure intensity is corrected by superimposing the PSF dependent on edge position information, instead of a simple convolution operation.

The point spread function dependent on edge position information in Embodiment 1 is defined by, for example, a distribution function using the shift amount of the center-of-gravity position of the exposure intensity distribution. In other words, the point spread function dependent on edge position information in Embodiment 1 is defined by, for example, a distribution function using a shift amount s for shifting the center-of-gravity position of the exposure intensity distribution. The distribution function is defined using a Gaussian function. The point spread function gⱼ(x) dependent on edge position information is defined by the following Equation (3). As the edge position information, for example, a pattern area density ρ of a pixel is used. In Equation (3), the standard deviation σ of the point spread function gⱼ(x) dependent on edge position information changes depending on the difference in blur between a writing apparatus for advanced processes and an older-generation writing apparatus. In addition, when a fixed standard deviation σ is used, the shift amount s changes depending on the pattern area density ρ of the target pixel. In Equation (3), B is a coefficient for normalization.

$${g}_{j} ( x ) = B exp ( - \frac{{( x + s )}^{2}}{{σ}^{2}} ) \qquad ( 3 )$$

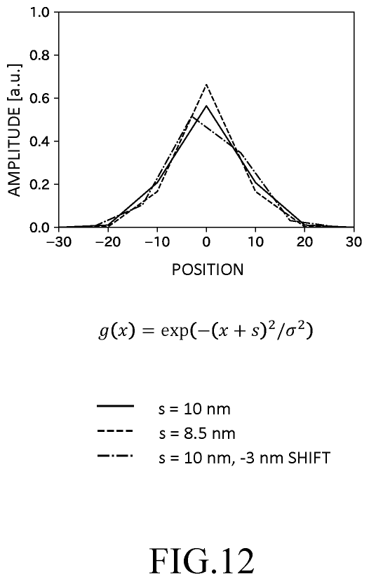

FIG. 12 is a diagram showing an example of the intensity distribution when the standard deviation and the shift amount are varied in Embodiment 1. In FIG. 12, the vertical axis indicates amplitude, and the horizontal axis indicates position. In the graph of FIG. 12, discretely sampled results are connected by straight lines. The value of the additional blur is defined, for convenience, by the standard deviation σ of the PSF. In the example of FIG. 12, a graph with a standard deviation σ=10 nm and a shift amount s=0, a graph with a standard deviation σ=8.5 nm and a shift amount s=0, and a graph with a standard deviation σ=10 nm and a shift amount s=−3 nm are shown as examples. By increasing the additional blur, the distribution is smoothed. In addition, by setting the shift amount to a value other than 0, the center-of-gravity position of the distribution can be shifted.

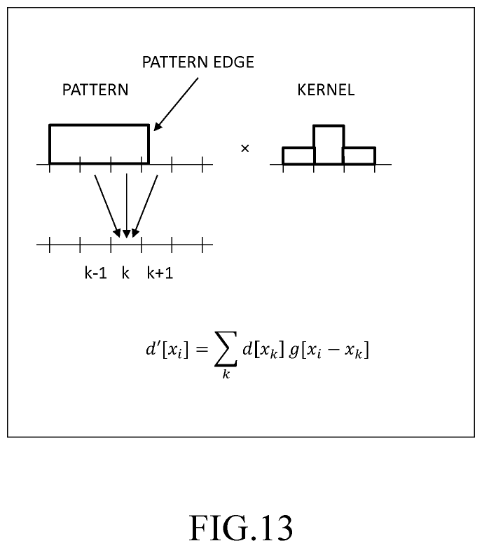

FIG. 13 is a diagram for explaining exposure intensity correction calculation using a fixed point spread function in Comparative Example 3 of Embodiment 1.

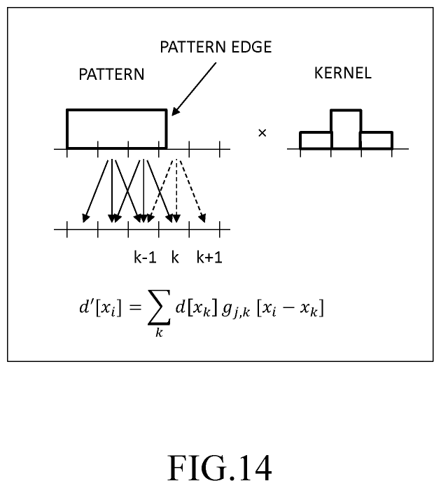

FIG. 14 is a diagram for explaining exposure intensity correction calculation using a point spread function dependent on edge position information in Embodiment 1. In the equations of FIGS. 13 and 14, i indicates an index of a target pixel. k indicates an index of the target pixel i and surrounding pixels with the target pixel i as the center.

In the example of FIG. 13, a case is shown in which a corrected exposure intensity d′ is calculated by performing a convolution operation using the same point spread function g(x) for the on-grid pattern and the off-grid pattern. As a result, as described above, a deviation occurs for pixels of the off-grid pattern. In contrast, in Embodiment 1, as shown in the example of FIG. 14, the corrected exposure intensity d′ is calculated using a point spread function gⱼ(x) dependent on edge position information for the on-grid pattern and the off-grid pattern. In the example of FIG. 14, for non-gray pixels having a pattern area density ρ of 100%, the point spread function gⱼ(x) with s=0 is used. For gray pixels having a pattern area density ρ other than 0% and 100%, the point spread function gⱼ(x) in which the shift amount s changes according to the pattern area density ρ is used. The equation shown in FIG. 14 is defined in terms of a convolution operation; however, its actual meaning is different from the convolution operation in that it is not a simple sum-of-products operation. Specifically, as shown in FIG. 14, the corrected exposure intensity d′ for each pixel is calculated as a total value of the remaining exposure intensity after the target pixel distributes a part of the exposure intensity to surrounding pixels and the exposure intensity distributed from the surrounding pixels.

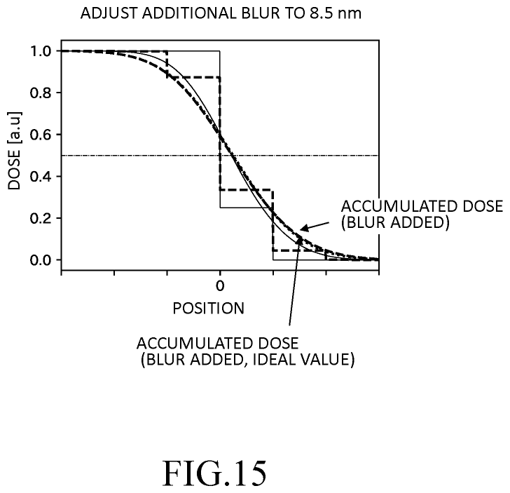

FIG. 15 is a diagram showing an example of the exposure intensity and the accumulated dose when an additional blur is added to pixels of an off-grid pattern in which the area density of pattern-edge pixels is 25% in Comparative Example 3 of Embodiment 1.

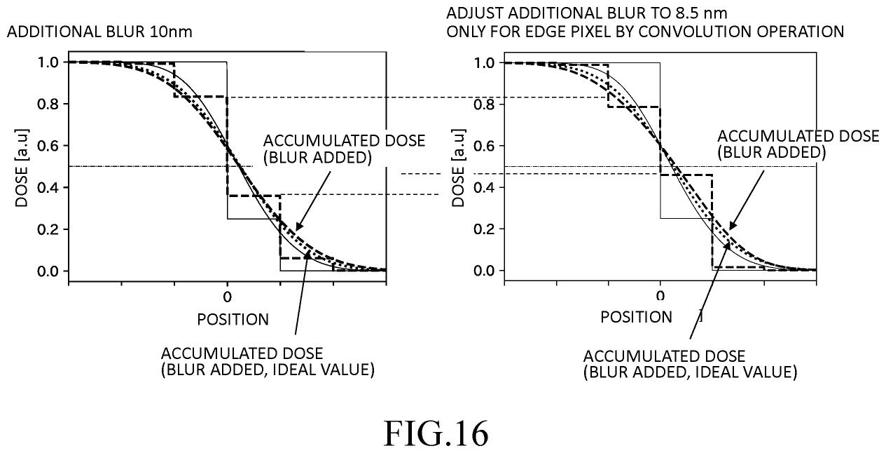

FIG. 16 is a diagram showing another example of the exposure intensity and the accumulated dose when an additional blur is added to pixels of an off-grid pattern in which the area density of pattern-edge pixels is 25% in Embodiment 1.

In the example of FIG. 11 described above, an additional blur of 10 nm is added, but in the example of FIG. 15, a case is shown in which an additional blur of 8.5 nm is added to all pixels of the area ratio map ρ by convolution using Equation (2), which is Comparison Example 2, under the conditions shown in FIG. 10.

The left graph in FIG. 16 is the same as FIG. 11. In the example of the right graph in FIG. 16, a case is shown in which, under the conditions shown in FIG. 10, an additional blur of 10 nm, which is the same as in FIG. 11, is added to pixels located inside the pattern and an additional blur of 8.5 nm is added to pixels having an area ratio less than 1 where the pattern edge is located.

In FIGS. 10 and 11, when an additional blur of 10 nm is added to an on-grid pattern using the method of FIG. 13, an accumulated dose close to the ideal is obtained; however, for an off-grid pattern, the accumulated dose distribution becomes wider than the ideal. Therefore, if the width of the additional blur is changed from 10 nm to 8.5 nm, as shown in FIG. 15, even for the off-grid pattern, an accumulated dose corresponding to the case where an additional blur of 10 nm is added to the ideal accumulated dose distribution is obtained. However, in Comparative Example 2 using convolution of Equation (2), since the same convolution operation is applied to all pixels, it is not possible to add additional blurs having different widths to the on-grid pattern and the off-grid pattern.

On the other hand, by adding an additional blur of 10 nm to all pixels in the off-grid pattern using the method of FIG. 13, an accumulated dose wider than the ideal is obtained, as shown in the left graph in FIG. 16. As a countermeasure, when a blur of 8.5 nm instead of 10 nm is added only to pixels at the pattern edge using the method of FIG. 14, as shown in the right graph in FIG. 16, the exposure intensity of the pixels at the pattern edge increases, and conversely, the exposure intensity gradient decreases, causing the accumulated dose to deviate from the ideal value.

Therefore, by adjusting the additional blur to be smaller than the size of the blur to be added, the accumulated dose of the pixels of the off-grid pattern can be brought closer to the ideal value. In addition, when adjusting the additional blur, a method of adjusting the size of the additional blur to be smaller than the size of the blur to be added only for pixels at the pattern edge does not bring the accumulated dose distribution close to the ideal.

On the other hand, with a method of adding an additional blur by exposure intensity correction calculation using the point spread function dependent on edge position information shown in FIG. 14, which is Embodiment 1, an accumulated dose distribution close to the ideal accumulated dose distribution with an additional blur added can be obtained by adjusting the shift amount s as shown below.

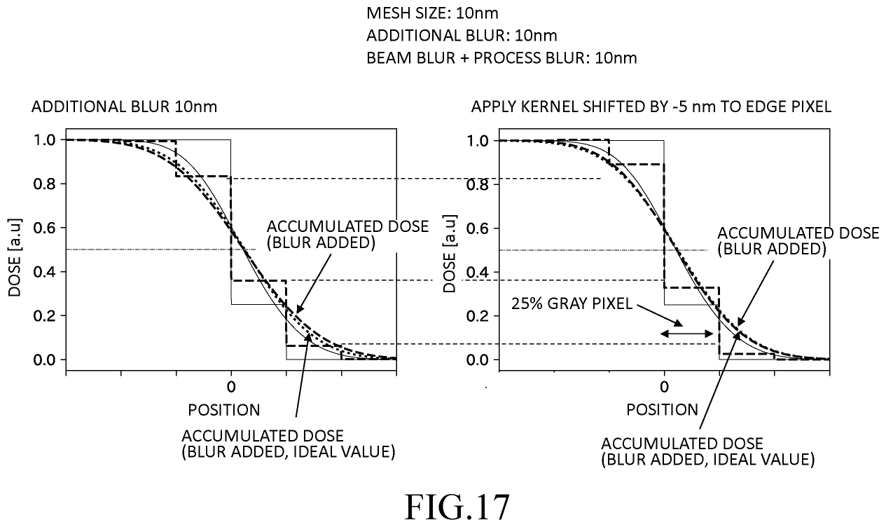

FIG. 17 is a diagram showing another example of the exposure intensity and the accumulated dose when an additional blur is added to pixels of an off-grid pattern with an area density of 25% in Embodiment 1. The left graph in FIG. 17 is the same as that in FIG. 11. The right graph in FIG. 17 shows a case where the center-of-gravity position is shifted by a shift amount s=−5 nm under the conditions shown in FIG. 11 (additional blur of 10 nm). As shown in the left graph in FIG. 17, the accumulated dose deviates when the additional blur is 10 nm, but as shown in the right graph in FIG. 17, even with the same additional blur of 10 nm, the accumulated dose can be matched to the ideal value by shifting the center-of-gravity position with a shift amount s=−5 nm.

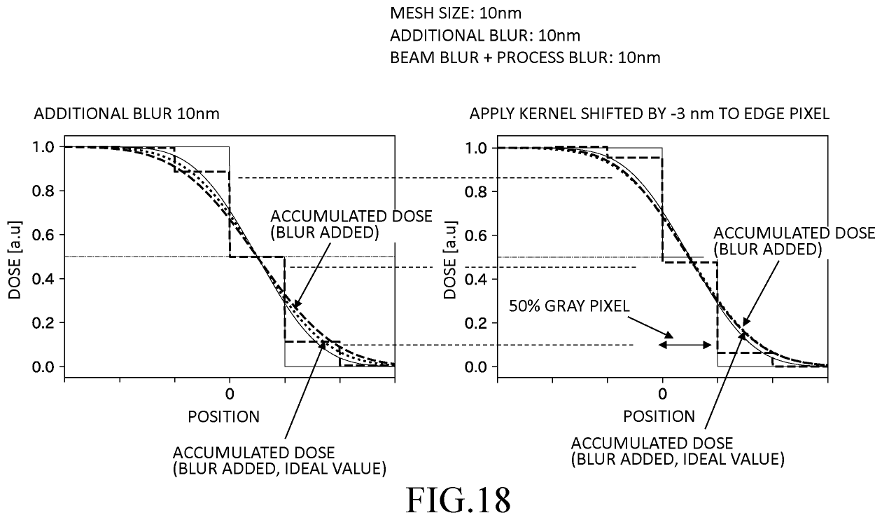

FIG. 18 is a diagram showing an example of the exposure intensity and the accumulated dose when an additional blur is added to pixels of an off-grid pattern with an area density of 50% in Embodiment 1. The right graph in FIG. 18 shows a case where the pixel size is 10 nm, the sum of the beam blur and the process blur is 10 nm, and the additional blur is 10 nm. The right graph in FIG. 18 shows a case where the center-of-gravity position is shifted by a shift amount s=−3 nm under the conditions of the left graph in FIG. 18. As shown in the left graph in FIG. 18, the accumulated dose deviates when the additional blur is 10 nm, but as shown in the right graph in FIG. 18, even with the same additional blur of 10 nm, the accumulated dose can be matched to the ideal value by shifting the center-of-gravity position with a shift amount s=−3 nm.

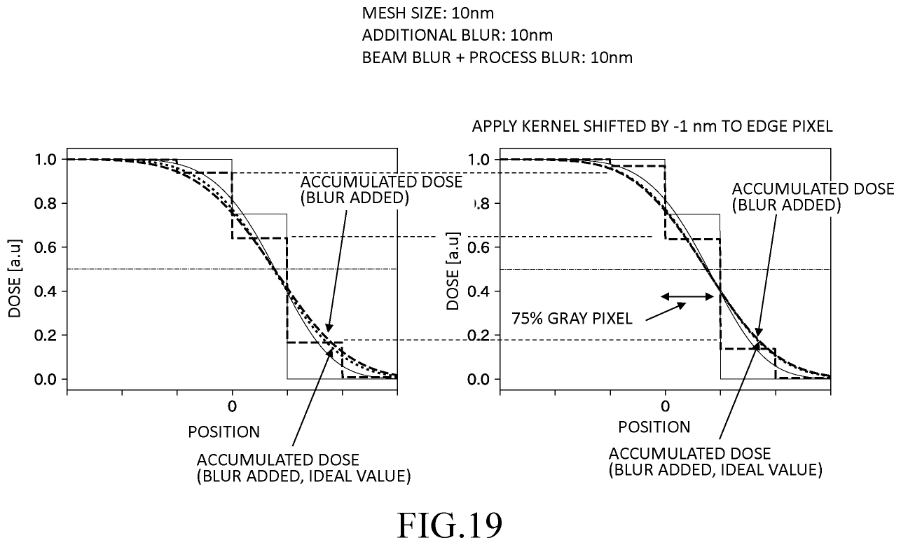

FIG. 19 is a diagram showing an example of the exposure intensity and the accumulated dose when an additional blur is added to pixels of an off-grid pattern with an area density of 75% in Embodiment 1. The right graph in FIG. 19 shows a case where the pixel size is 10 nm, the sum of the beam blur and the process blur is 10 nm, and the additional blur is 10 nm. The right graph in FIG. 19 shows a case where the center-of-gravity position is shifted by a shift amount s=−1 nm under the conditions of the left graph in FIG. 19. As shown in the left graph in FIG. 19, the accumulated dose deviates when the additional blur is 10 nm, but as shown in the right graph in FIG. 19, even with the same additional blur of 10 nm, the accumulated dose can be matched to the ideal value by shifting the center-of-gravity position with a shift amount s=−1 nm.

As indicated by the above results, by changing the shift amount according to the pattern area density ρ of the target pixel, the accumulated dose that deviates when only the additional blur is added can be matched to the ideal value.

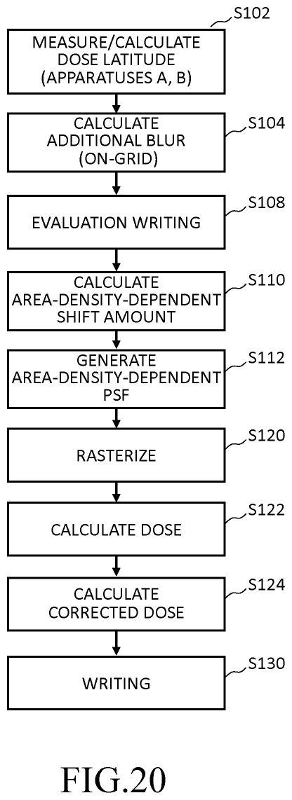

FIG. 20 is a flowchart showing an example of main steps of a writing method according to Embodiment 1. In FIG. 20, the writing method according to Embodiment 1 performs a series of steps, including a margin measurement/calculation step (S102), an additional blur calculation step (S104), an evaluation writing step (S108), an area-density-dependent shift amount calculation step (S110), an area-density-dependent PSF generation step (S112), a rasterization step (S120), an exposure intensity calculation step (S122), a corrected exposure intensity calculation step (S124), and a writing step (S130).

In the margin measurement/calculation step (S102), the margin for an on-grid pattern is measured (calculated) using the high-precision writing apparatus 100 for advanced processes. Similarly, the margin for an on-grid pattern is measured (calculated) using an older-generation, low-precision writing apparatus to be matched.

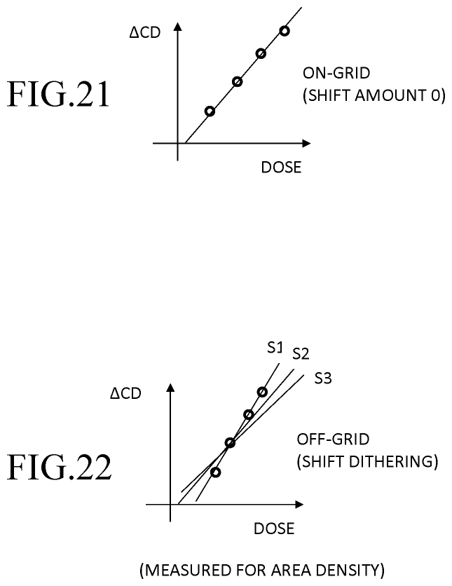

FIG. 21 is a diagram showing an example of the relationship between a dimensional variation and an exposure intensity in Embodiment 1. In FIG. 21, the vertical axis indicates a dimensional variation. The horizontal axis indicates an exposure intensity. A margin DL indicates a dimensional variation with respect to the exposure intensity, in other words, the slope of the graph in FIG. 21. Since the pattern is an on-grid pattern, the shift amount is set to zero, and each apparatus writes a plurality of evaluation patterns on a resist-coated evaluation substrate while varying the exposure intensity, without additional blur. By measuring the dimensions of the resist patterns for each exposure intensity obtained after development using a separate position measurement apparatus, it is possible to obtain relationship data between the dimensional variation and the exposure intensity in the high-precision writing apparatus 100 for advanced processes and relationship data between the dimensional variation and the exposure intensity in the older-generation, low-precision writing apparatus. Each piece of relationship data is input from outside the writing apparatus 100 and stored in the storage device 140 or the like.

Then, the margin calculation unit 60 calculates the margin DL of the high-precision writing apparatus 100 for advanced processes and the margin DL of the older-generation, low-precision writing apparatus by referring to the respective pieces of relationship data.

In the additional blur calculation step (S104), the additional blur calculation unit 62 calculates an amount of additional blur for matching the resolution of the high-precision writing apparatus 100 for advanced processes to the resolution of the older-generation, low-precision writing apparatus. For example, an additional blur for matching the margin DL of the high-precision writing apparatus 100 for advanced processes to the margin DL of the older-generation, low-precision writing apparatus is calculated. The relationship between the margin and the additional blur may be measured in advance through experiments or simulations. From such a relationship, the amount of additional blur is calculated. As described above, the amount of additional blur is defined as the value of the standard deviation σ of the point spread function gⱼ(x). In other words, the standard deviation σ of a Gaussian function is set so that a pattern shape obtained by writing using the high-precision writing apparatus 100 for advanced processes, which has small beam blur, matches a pattern shape obtained by writing using an older-generation, low-precision writing apparatus having large beam blur.

In the area density and shift amount setting step (S106), the combination setting unit 64 sets a plurality of combinations using a plurality of pattern area densities ρ and a plurality of shift amounts s.

In the evaluation writing step (S108), the high-precision writing apparatus 100 for advanced processes writes, on a resist-coated evaluation substrate, a plurality of evaluation patterns in which the off-grid pattern has a plurality of pattern area densities ρ, while varying the shift amount s for pixels of each pattern area density ρ and varying the exposure intensity. At this time, the calculated amount of additional blur is applied. The exposure intensity of each pixel in which a plurality of evaluation patterns are arranged is corrected by performing a superposition calculation using, as a kernel, the PSF to which the additional blur has been applied, as shown in FIG. 14. For each combination of the pattern area density ρ and the shift amount and for each exposure intensity, the dimensions of the resist patterns obtained after development are measured using a separate position measurement apparatus. The obtained results are input from outside the writing apparatus 100 and stored in the storage device 140, for example.

In the area density dependent shift amount calculation step (S110), first, the margin calculation unit 64 calculates the margin for each pattern area density ρ and each shift amount s.

FIG. 22 is a diagram showing an example of the relationship among the shift amount, the dimensional variation, and the exposure intensity in an off-grid pattern in Embodiment 1. In FIG. 22, the vertical axis indicates a dimensional variation ΔCD. The horizontal axis indicates an exposure intensity. In addition, measurement data is plotted for each shift amount s. In addition, such a relationship is created for each pattern area density ρ.

The shift amount calculation unit 66 calculates, for each pattern area density ρ, a shift amount for matching the margin of an on-grid pattern calculated from the results obtained with the older-generation writing apparatus, based on the calculated margin for each shift amount. If there is no matching margin, the shift amount s for each pattern area density ρ is calculated by linear interpolation. In other words, a shift amount is calculated to match the exposure intensity gradient of an off-grid pattern, in which the edge of the figure does not match the edge of the pixel 36, to the exposure intensity gradient of an on-grid pattern, in which the edge of the figure matches the edge of the pixel 36. In addition, the shift amount s for an on-grid pattern with a pattern area density ρ=100% is set to zero.

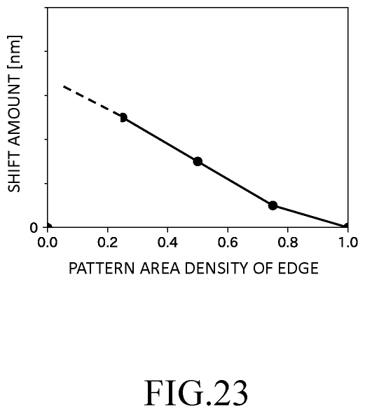

FIG. 23 is a diagram showing an example of the relationship between the shift amount and the pattern area density in Embodiment 1. In FIG. 23, the vertical axis indicates a shift amount. The horizontal axis indicates the pattern area density of pixels of the off-grid pattern. As shown in the example of FIG. 23, the optimal shift amount s changes dependent on the pattern area density of pixels of the off-grid pattern.

In the area-density-dependent PSF generation step (S112), the PSF generation unit 68 (function calculation unit) calculates, for each pattern area density, a function to provide a desired exposure intensity gradient. In other words, the PSF generation unit 68 (function calculation unit) calculates, for each pattern area density ρ, an area-density-dependent PSF to provide a desired exposure intensity gradient. The area-density-dependent PSF matches the exposure intensity gradient of the off-grid pattern, in which the edge of the figure do not match the edge of the pixel 36, to the exposure intensity gradient of the on-grid pattern, in which the edge of the figure matches the edge of the pixel 36. Specifically, the operation is as follows. The PSF generation unit 68 generates the area-density-dependent PSF using the calculated amount of additional blur and the calculated shift amount s for each pattern area density ρ. The area-density-dependent PSF may be obtained by applying Equation (3). For the standard deviation σ, the calculated amount of additional blur is applied. In the area-density-dependent PSF, the shift amount s differs dependent on the pattern area density ρ (pattern area ratio). In other words, the shift amount depends on the pattern area ratio. For the shift amount s, the shift amount s for each pattern area density ρ is applied.

As described above, the area-density-dependent PSF for matching the resolution of the high-precision writing apparatus 100 for advanced processes to the resolution of an older-generation, low-precision writing apparatus can be obtained as a kernel. Using such a kernel, a writing process is performed to write a desired pattern on the writing target object 101.

In the rasterization step (S120), the rasterization processing unit 54 (an example of an area density calculation unit) reads writing data from the storage device 140, for example, for each stripe region 32, and calculates, for each pixel 36 (small region) of a plurality of pixels 36 that are electron beam irradiation unit regions obtained by dividing the stripe region 32 (an example of a writing region) of the target object 101, the pattern area density ρ of the figure arranged in the pixel 36. In other words, the rasterization processing unit 54 calculates the pattern area density of the figure arranged in each pixel 36 of the plurality of pixels 36 that are electron beam irradiation unit regions obtained by dividing the writing region of the target object 101. The pattern area density for each pixel 36 is stored in, for example, the storage device 142.

In the exposure intensity calculation step (S122), the exposure intensity calculation unit 56 calculates, for each pixel 36, an exposure intensity d with which the pixel 36 is irradiated. In other words, the exposure intensity calculation unit 56 reads a pattern area density for each pixel 36 from, for example, the storage device 142 and calculates an exposure intensity for each pixel 36. Specifically, the operation is as follows. First, the exposure intensity calculation unit 56 calculates a proximity effect-corrected exposure intensity Dp(x) for correcting the proximity effect for each proximity mesh region. The unknown proximity effect-corrected exposure intensity Dp(x) can be defined by a threshold model for proximity effect correction similar to conventional methods, using a back scattering coefficient η, an exposure intensity threshold Dth of the threshold model, a pattern area density ρ″ of the proximity mesh region, and a distribution function f(x). The proximity effect-corrected exposure intensity Dp(x) is calculated as a relative value normalized with base exposure intensities of the beam Dbase set to 1. The size of the proximity mesh region is preferably set to about 1/10 of the radius of influence of the proximity effect, for example, about 1 μm.

Then, the exposure intensity calculation unit 56 calculates, for each pixel 36, the exposure intensity d(x) (dose) to be applied to the pixel 36. The exposure intensity d(x) may be calculated, for example, as a value obtained by multiplying the base exposure intensities of the beam Dbase by the proximity effect-corrected exposure intensity Dp and the pattern area density ρ of the target pixel 36. The base exposure intensities of the beam Dbase can be defined as, for example, Dth/(½+η). As described above, it is possible to obtain, for each pixel, the exposure intensity d(x) in which the proximity effect has been corrected and which is based on the layout of a plurality of figures defined in writing data. Alternatively, it is also preferable that the exposure intensity calculation unit 56 defines the exposure intensity d(x) for each pixel as the exposure intensity d(x) normalized with the base exposure intensities of the beam Dbase set to 1. In such a case, the exposure intensity d(x) may be calculated, for example, as a value obtained by multiplying the proximity effect-corrected exposure intensity Dp by the pattern area density ρ.

Then, the exposure intensity calculation unit 56 creates a dose map having the exposure intensities d(x) of the respective pixels 36 as its elements. In other words, the exposure intensity d(x) for each pixel is defined by associating each pixel (position) (x, y) with the exposure intensity d(x) of the pixel. The created dose map is stored in the storage device 142. The exposure intensity calculation unit 56 creates a dose map for the entire writing region 30 in which writing processing is performed in accordance with the writing data (chip data).

In addition, when performing multi-writing, a dose map is created for each of writing processes corresponding to each multi-writing count.

In the corrected exposure intensity calculation step (S124), the corrected exposure intensity calculation unit 57 calculates, for each pixel 36, a corrected exposure intensity of the pixel 36 using a function corresponding to the pattern area density of the pixel 36. In other words, the corrected exposure intensity calculation unit 57 calculates, for each pixel 36, a corrected exposure intensity d′(x) obtained by correcting the exposure intensity d(x) of the pixel 36 while switching the PSF (function) gⱼ(x) according to the pattern area density ρ of the pixel 36. The equation for calculating the corrected exposure intensity d′(x) can be defined by the following Equation (4), in the same manner as the equation shown in FIG. 14.

[Equation 4]

d′(xᵢ)=Σₖd(xᵢ)g_{j,k}(xᵢ−xₖ) (4)

By such correction, the corrected exposure intensity d′(x) of each pixel is calculated, as shown in FIG. 14, as the sum of the remaining exposure intensity obtained by distributing a part of the exposure intensity of the target pixel to surrounding pixels and the exposure intensity distributed from the surrounding pixels.

The corrected exposure intensity calculation unit 57 creates a corrected dose map having the corrected exposure intensity d′(x) of each pixel 36 as its element.

The beam irradiation time calculation unit 58 calculates a beam irradiation time t for each pixel 36 using the corrected exposure intensity d′(x) (corrected dose). The beam irradiation time t for each pixel 36 can be calculated by dividing the corrected exposure intensity d′(x) of the pixel by a current density J. When the corrected exposure intensity d′(x) defined in the corrected dose map is normalized with the base exposure intensities of the beam Dbase set to 1, the beam irradiation time t for each pixel 36 can be calculated by dividing a value, which is obtained by multiplying the corrected exposure intensity d′(x) by the base exposure intensities of the beam Dbase, by the current density J.

Then, the data processing unit 59 rearranges the obtained beam irradiation time data for each pixel 36 in shot order and stores the data in the storage device 142. The transfer processing unit 74 transfers the beam irradiation time data to the deflection control circuit 130 in shot order.

In the writing step (S130), under the control of the writing control unit 72, the writing mechanism 150 writes a pattern on the target object 101 using the multiple beams 20 based on the corrected exposure intensity d′(x).

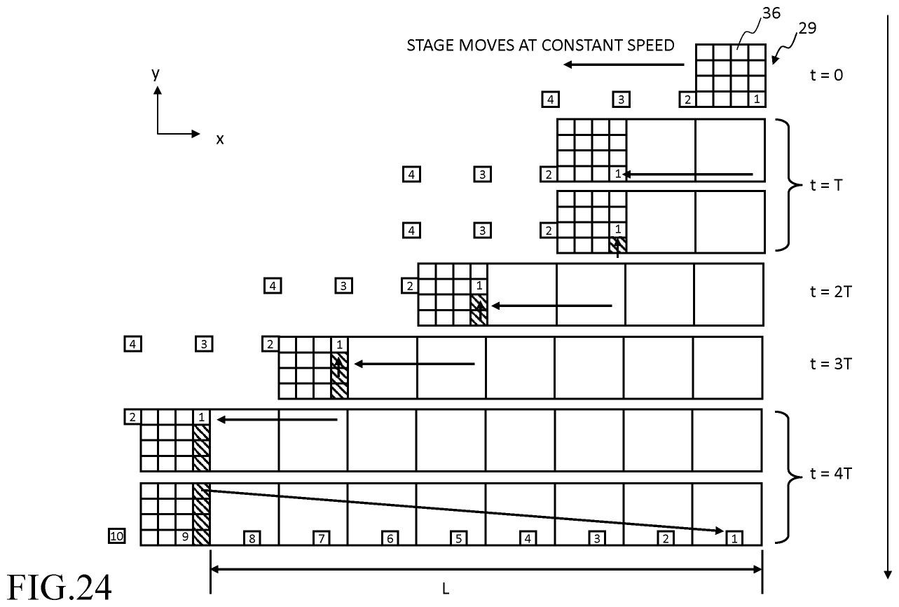

FIG. 24 is a diagram for explaining an example of a multi-beam writing operation in Embodiment 1. In the example of FIG. 24, a case is shown in which each sub-irradiation region 29 including one beam irradiation position of the multiple beams 20 and surrounded with the pitch between beams is written with four different beams. In addition, in the example of FIG. 24, a writing operation is shown in which the XY stage 105 moves continuously at a speed for movement by a distance L of eight beam pitches while writing a ¼ region (1/the number of beams used for irradiation) in each sub-irradiation region 29. In the example of FIG. 24, a case is shown in which each sub-irradiation region 29 is formed by, for example, 4×4 pixels. In the writing operation shown in the example of FIG. 24, for example, four different pixels 36 within the same sub-irradiation region 29 are written (exposed) by performing four shots of the multiple beams 20 with a shot cycle T while shifting the irradiation position (pixel 36) sequentially by the sub-deflector 209 during the movement of the XY stage 105 by the distance L of eight beam pitches. The irradiation region 34 is caused to follow the movement of the XY stage 105 by collectively deflecting all of the multiple beams 20 with the main deflector 208, so that the relative position of the irradiation region 34 with respect to the target object 101 does not shift due to the movement of the XY stage 105, while writing (exposing) the four pixels 36. In other words, tracking control is carried out. When one tracking cycle ends, the tracking is reset to return to the previous tracking start position. In addition, since the writing of the first pixel column from the right of each sub-irradiation region 29 has been completed, in the next tracking cycle after tracking reset, the sub-deflector 209 first performs deflection to match (shift) the writing position of the beam so as to write, for example, the second pixel column from the right that has not yet been written in each sub-irradiation region 29. By repeating this operation while writing the stripe region 32, the position of the irradiation region 34 (34a to 34o) of the multiple beams 20 is sequentially moved as shown in the lower diagram of FIG. 4 to perform writing.

As described above, according to Embodiment 1, in a high-precision writing apparatus, the exposure intensity of each pixel 36 is corrected by using the area-density-dependent PSF as a kernel so that the pattern of an exposure dose distribution obtained by a low-precision writing apparatus can be obtained. Therefore, with a high-precision writing apparatus, it is possible to write the pattern of an exposure dose distribution obtained by a low-precision writing apparatus without replacing hardware.

Up to now, the embodiment has been described with reference to specific examples. However, the invention is not limited to these specific examples. The functions of the processes described in the above embodiment may be executed by a computer. Then, a program for causing a computer to execute such functions of the processes may be stored, for example, in a non-transitory computer-readable storage medium storing a program, such as a magnetic disk drive.

In addition, the description of parts that are not directly required for the description of the invention, such as the apparatus configuration or the control method, is omitted. However, the required apparatus configuration or control method can be appropriately selected and used. For example, although the description of the control unit configuration for controlling the writing apparatus 100 is omitted, it is needless to say that the required control unit configuration can be appropriately selected and used.

In addition, all charged particle beam writing methods and charged particle beam writing apparatuses that include the elements of the invention and that can be appropriately redesigned by those skilled in the art are included in the scope of the invention.

Additional advantages and modification will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A charged particle beam writing method, comprising:
calculating a pattern area density of a figure arranged in each of a plurality of small regions, each small region being an irradiation unit region of a charged particle beam obtained by dividing a writing region of a target object;
calculating an exposure intensity for each of the small regions;
calculating, for each pattern area density, a function to provide a desired exposure intensity gradient;
calculating, for each of the small regions, a corrected exposure intensity of the small region using a function corresponding to the pattern area density of the small region; and
writing a pattern on the target object using a charged particle beam based on the corrected exposure intensity.

2. The method according to claim 1,
wherein the function is defined by a distribution function using a shift amount of a center-of-gravity position of an exposure intensity distribution, and
the shift amount depends on a pattern area ratio.

3. The method according to claim 1,
wherein the function matches an exposure intensity gradient of an off-grid pattern to an exposure intensity gradient of an on-grid pattern, an edge of the figure being not matched to an edge of the small region in the off-grid pattern and an edge of the figure being matched to an edge of the small region in the on-grid pattern.

4. The method according to claim 1,
wherein the function is set so that a pattern shape obtained by writing using a writing apparatus having a small beam blur matches a pattern shape obtained when writing is performed using a writing apparatus having a large beam blur.

5. A charged particle beam writing apparatus, comprising:
a pattern area density calculation circuit configured to calculate a pattern area density of a figure arranged in each of a plurality of small regions, each small region being an irradiation unit region of a charged particle beam obtained by dividing a writing region of a target object;
an exposure intensity calculation circuit configured to calculate an exposure intensity for each of the small regions;
a function calculation circuit configured to calculate, for each pattern area density, a function to provide a desired exposure intensity gradient;
a corrected exposure intensity calculation circuit configured to calculate, for each of the small regions, a corrected exposure intensity of the small region using a function corresponding to the pattern area density of the small region; and
a writing mechanism configured to write a pattern on the target object using a charged particle beam based on the corrected exposure intensity.

6. A non-transitory computer-readable storage medium storing a program for causing a computer to execute processing comprising:
calculating a pattern area density of a figure arranged in each of a plurality of small regions, each small region being an irradiation unit region of a charged particle beam obtained by dividing a writing region of a target object;
storing the pattern area density for each of the small regions in a storage device;
reading the pattern area density for each of the small regions from the storage device and calculating an exposure intensity for each of the small regions;
calculating, for each pattern area density, a function to provide a desired exposure intensity gradient; and
calculating, for each of the small regions, a corrected exposure intensity of the small region using a function corresponding to the pattern area density of the small region and outputting the calculated corrected exposure intensity.
